(19) United States
(12) Patent Application Publication
(10) Pub. No.: US 2015/0093893 A1
(43) Pub. Date: Apr. 2, 2015

(54) PROCESS OF FORMING SEED LAYER IN VERTICAL TRENCH/VIA

(71) Applicant: United Microelectronics Corporation, Hsinchu (TW)

(72) Inventors: Yi-Fang Tao, Taichung City (TW); Ching-Wei Hsu, Changhua County (TW); Hsin-Yu Chen, Nantou County (TW); Tsun-Min Cheng, Changhua County (TW); Yung-Chien Kung, Tainan City (TW); Chi-Mao Hsu, Tainan County (TW); Guo-Wei Chen, Changhua County (TW); Huei-Ru Tsai, Kaohsiung City (TW); Jia-Rong Li, Pingtung County (TW)

(73) Assignee: UNITED MICROELECTRONICS CORPORATION, HSINCHU (TW)

(21) Appl. No.: 14/044,855

(22) Filed: Oct. 2, 2013

(51) Int. Cl. H01L 21/768

(52) U.S. Cl. CPC H01L 21/76879; H01L 21/76843
USPC 438/653

(57) ABSTRACT

In a process of forming a seed layer, particularly in a vertical trench or via, a semiconductor substrate having a dielectric structure and a hard mask structure thereon is provided. An opening is formed in the hard mask structure, and a trench or via is formed in the dielectric structure in communication with the opening, wherein an area of the opening is greater than that of an entrance of the trench or via. A seed layer is then deposited in the trench or via through the opening, and then subjected to a reflow process.

### TECHNICAL FIELD

The present invention relates to a process of forming a seed layer, and more particularly to a process of forming a seed layer in a vertical trench/via.

### DESCRIPTION OF THE RELATED ART

Conventionally, multi-level interconnection is formed in an integrated circuit by dry-etching a metal layer, e.g. aluminum layer, into a desired metal conductor pattern and then performing dielectric gap filling. The conventional process, however, would encounter problems when the metal material is changed from aluminum to copper that has a lower resistivity and is difficult to be dry etched. Therefore, a copper damascene process becomes popular for forming the multi-level interconnection. As is known to those skilled in the art, a copper damascene process is advantageous as not involving any etching procedure of metal layer. Instead, a trench or via is first formed in a dielectric layer, followed by filling the trench or via with a metal conductor and performing a planarization process.

For filling the metal conductor into the trench or via, a seed layer of the metal conductor needs to be formed in the trench or via first. Subsequently, an electroplating process is performed with the seed layer. Unfortunately, copper aggregation likely occurs while forming the seed layer in the copper damascene process, which might narrow or seal the opening of the trench or via. The gap filling capability would thus be deteriorated.

### BRIEF SUMMARY

Therefore, the present invention provides a process of forming a seed layer, which is applicable to the copper damascene process and capable of solving the aggregation problem.

In an embodiment, the present invention provides a process of forming a seed layer, which includes providing a semiconductor substrate having a dielectric structure and a hard mask structure thereon, an opening being formed in the hard mask structure, a trench or via being formed in the dielectric structure in communication with the opening, and an area of the opening being greater than that of an entrance of the trench or via; depositing a seed layer in the trench or via through the opening; and reflowing the seed layer.

For example, the reflowing step may be implemented with thermal reflow. The seed layer may be deposited by way of physical vapor deposition (PVD) or chemical vapor deposition (CVD). The process according to the present invention may optionally include a redeposition step of the seed layer by way of PVD and CVD after the thermal reflow.

In an embodiment, the opening can be formed in the hard mask structure by: partially removing the SiON layer, the Ti layer and the TiN layer to form a trench-defining opening; and performing a pull back procedure to partially remove the TiN layer and the Ti layer of the hard mask structure in the trench-defining opening after completing the formation of the trench or via, thereby forming the opening having the area greater than that of the entrance of the trench or via and rendering a rounded corner of the TiN layer while retaining a sharp corner of the SiON layer in the opening.

For example, the pull back procedure is performed with an EKC™ 580 CuSolve™ Post-Etch Residue Remover produced by DuPont™, which has an etch rate of about 10˜250 Å/min for the TiN layer/Ti layer and an etch rate less than 1 Å/min for the SiON layer.

Preferably, the process according to the present invention further includes forming a barrier layer of tantalum (Ta) or tantalum nitride (TaN) in the trench or via before depositing the seed layer in the trench or via.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIGS. 1A through FIG. 1G are cross-sectional diagrams illustrating steps of a process of forming a seed layer in a vertical trench according to an embodiment of the present invention.

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items.

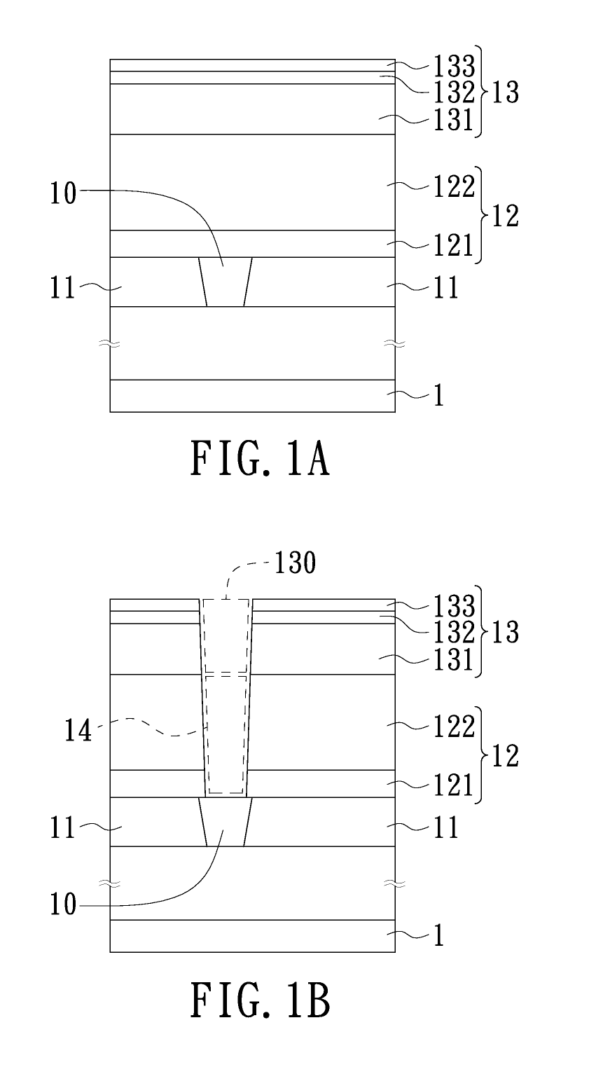

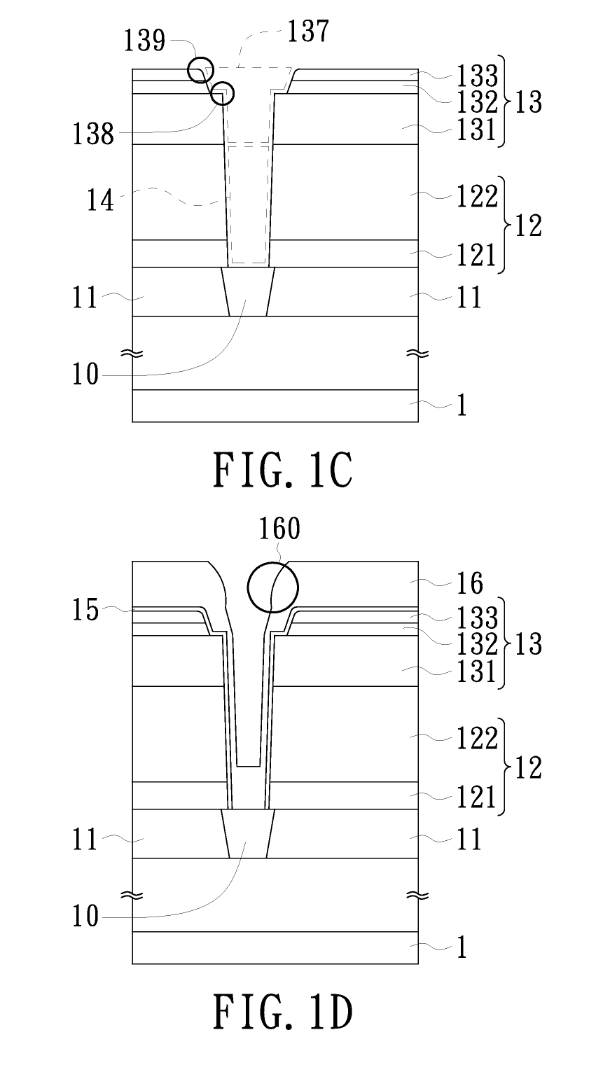

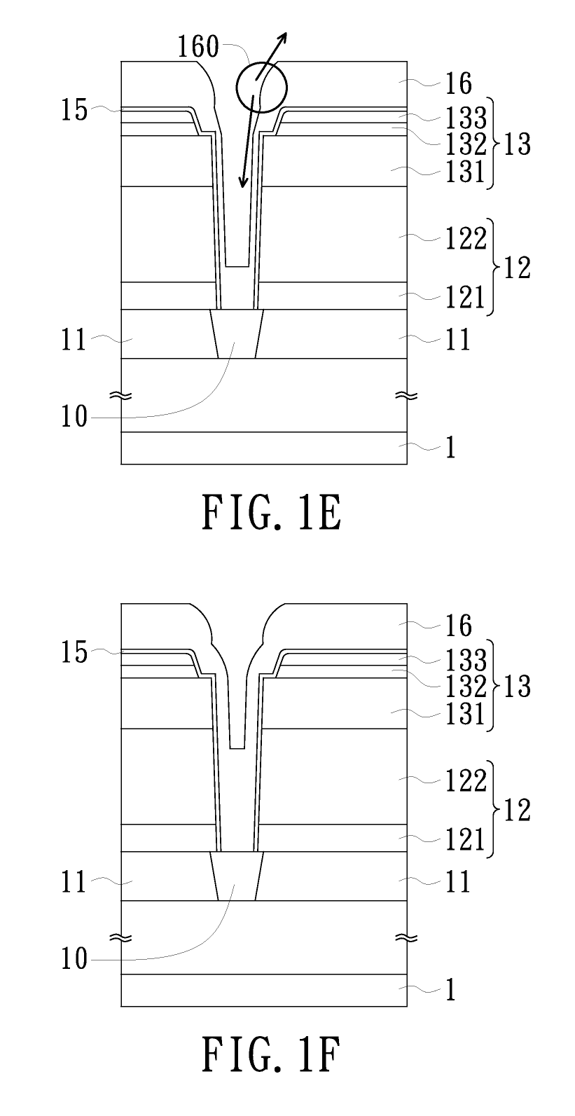

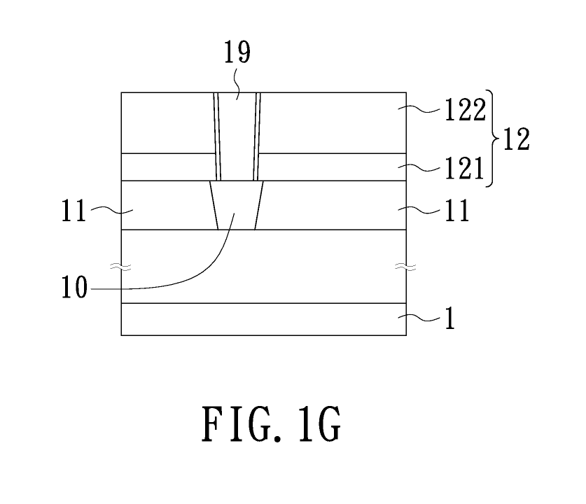

Please refer to FIGS. 1A˜FIG. 1G which illustrate a process of forming a seed layer according to an embodiment of the present invention. On a semiconductor substrate 1, an underlying conductive structure 10 and an underlying dielectric layer 11 are formed optionally, as shown in FIG. 1A. Subsequently, a dielectric structure 12 and a hard mask structure 13 are formed on the underlying conductive structure 10 and the underlying dielectric layer 11. The dielectric structure 12 is composed of a first layer 121 made of silicon nitride doped with carbon (NDC) and a second layer 122 made of ultra low K (ULK) overlying the first layer 121. The hard mask structure 13 is composed of a silicon oxynitride (SiON) layer 131, a titanium (Ti) layer 132 and a titanium nitride (TiN) layer 133, each overlying the former one in sequential order.

Now refer to FIG. 1B. An opening 130 is created in the hard mask structure 13. Subsequently, a trench or via, e.g. a trench 14, can be formed in the dielectric structure 12 on the substrate 1 with the presence of the hard mask structure 13 and the opening 130, thus the opening 130 serves as a trench-defining opening.

In the subsequent procedure as illustrated in FIG. 1C, a pull back process is performed on the hard mask structure 13 to specifically remove a part of the TiN layer 133 and the Ti layer 132 forming a side wall of the opening 130 so as to enlarge an area of the opening 130 and rounding a corner 139 of the TiN layer 133 while retaining a sharp corner 138 of the SiON layer 131. For achieving the abovementioned objects, an EKC™ 580 CuSolve™ Post-Etch Residue Remover produced by DuPont™, which has an etch rate of about 10˜250 Å/min for both the TiN layer 133 and the Ti layer 132 and an etch rate less than 1 Å/min for the SiON layer 131, can be used in this embodiment. However, it is not to limit the pull back agent to this specific one, and any other compound, composition or formula having a specific etching rate for the TiN layer 133 and/or Ti layer 132 compared to the other layers can also be used.

After the pull back process is completed, a barrier layer 15 and a seed layer 16 are formed in the trench 14 through the enlarged opening 130, as shown in FIG. 1D. The seed layer 16 can be formed of copper (Cu), ruthenium (Ru) or mixture thereof by way of physical vapor deposition (PVD) or chemical vapor deposition (CVD). As known, copper atoms are readily diffused and react with silicon or silicon oxide to produce copper silicon, which would deteriorate the property of the integrated circuit or even break down the integrated circuit. In addition, the adhesion of copper to most of the commonly-used dielectric material is poor. Therefore, the barrier layer 15 functions as a diffusion barrier to solve these problems. In this embodiment, the barrier layer 15 can be formed of, but not limited to, tantalum (Ta) or tantalum nitride (TaN). Any other suitable material having a diffusion-blocking capability and having features of low resistivity and good adhesion to copper can be used herein as the barrier layer. Since the TiN layer 133 is pulled back in the opening 130 while the corner of the SiON layer 131 remains being sharp, the PVD or CVD process would result in an overhang structure 160 of the seed layer 16 at the pulled back corner as well as the sharp corner 138 of the SiON layer 131. The (thickened) overhang structure 160 would narrow the trench 14 at the entrance of the trench 14.

Subsequently, in the procedure step as illustrated in FIG. 1E, a thermal reflow process is performed to increase atom mobility with thermal energy. By way of this process, the seed atoms redistribute to minimize energy. As a result, the atoms of the overhang structure 160 formed at the pulled back corner and the sharp corner will migrate upwards and downwards, as indicated by the arrows, due to the cohesion effect, and the effect of narrowing the entrance of the trench is diminished. Meanwhile, the flow of the seed atoms downward to the bottom of the trench improves the bottom coverage, as shown in FIG. 1F. The thermal reflow process can be performed at about 400 degrees C. for 0-100 seconds.

Afterwards, a redeposition process step can be optionally performed on the seed layer 16 for repairing the loss of the seed layer 16 from the side wall of the trench 14 in the thermal reflow process. For example, the reposition process is another PVD or CVD process using Cu, Ru or the mixture. The resulting seed layer 16 preferably has a vertical-like profile angle of 90 degrees plus/minus 5 degrees, and a thickness range of 150-600 angstroms.

The seed layer 16 is then used in an electroplating process or an electroless plating process to conduct the filling of a copper conductor 19 in the trench 14. Subsequently, a planarization process is performed to remove the hard mask structure 13 and a part of the copper conductor 19 so as to form the multi-level interconnection structure as shown in FIG. 1G.

The above description is given by way of example, and not limitation. Given the above disclosure, one skilled in the art could devise variations that are within the scope and spirit of the invention disclosed herein, including configurations ways of the recessed portions and materials or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

1. A process of forming a seed layer, comprising:
providing a semiconductor substrate having a dielectric structure and a hard mask structure thereon, an opening being formed in the hard mask structure, a trench or via being formed in the dielectric structure in communication with the opening, and an area of the opening being greater than that of an entrance of the trench or via;
depositing a seed layer in the trench or via through the opening; and
reflowing the seed layer,
wherein the hard mask structure includes:
a silicon oxynitride (SiON) layer formed over the semiconductor substrate;
a titanium (Ti) layer overlying the SiON layer; and
a titanium nitride (TiN) layer overlying the Ti layer,
wherein the opening is formed in the hard mask structure by:
partially removing the SiON layer, the Ti layer and the TiN layer to form a trench-defining opening; and
performing a pull back procedure to partially remove the TiN layer and the Ti layer of the hard mask structure in the trench-defining opening after completing the formation of the trench or via, thereby forming the opening having the area thereof greater than that of the entrance of the trench or via and rendering a rounded corner of the TiN layer while retaining a sham corner of the SiON layer in the opening.

2. The process according to claim 1 wherein the dielectric structure includes a first layer formed over the semiconductor substrate, and a second layer overlying the first layer, the second layer is of ultra low K (ULK) dielectric material , the first layer is of silicon nitride doped with carbon (NDC).

3. (canceled)

4. (canceled)

5. (canceled)

6. The process according to claim 1 wherein the semiconductor substrate further has an underlying conductive structure and an underlying dielectric layer below the dielectric structure.

7. The process according to claim 1 wherein the seed layer is deposited by way of physical vapor deposition (PVD) or chemical vapor deposition (CVD).

8. The process according to claim 1, further comprising forming a barrier layer of tantalum (Ta) or tantalum nitride (TaN) in the trench or via before depositing the seed layer in the trench or via.

9. The process according to claim 1 wherein the seed layer is a layer of copper (Cu) or ruthenium (Ru).

10. The process according to claim 9 wherein reflowing the seed layer is implemented with thermal reflow at about 400 degrees C. for 0˜100 seconds.

11. The process according to claim 10, further comprising a redeposition step of the seed layer by way of PVD and CVD after the thermal reflow.
